(19) United States
(12) Patent Application Publication
(10) Pub. No.: US 2021/0004771 A1
(43) Pub. Date: Jan. 7, 2021

(54) SYSTEM AND METHOD FOR MONITORING ELECTRIC APPLIANCES

(71) Applicant: YOUTILIGENT SMART SOLUTIONS (2014), Nir Am (IL)

(72) Inventors: Aviv LEVIN, Shoham (IL); Vadim HASHANSKY, Rishon Lezion (IL); Avichai BELITSKY, Oranit (IL)

(21) Appl. No.: 16/976,623

(22) PCT Filed: Feb. 28, 2019
(86) PCT No.: PCT/IL2019/050226

§ 371 Date: Aug. 28, 2020

Related U.S. Application Data
(60) Provisional application No. 62/636,173, filed on Feb. 28, 2018.

(51) Int. Cl. G06Q 10/00; G01R 31/56; G01R 21/133; G06Q 50/06; G06Q 10/08; G06Q 50/12; G05B 23/02; G07F 13/02; H02J 13/00

(52) U.S. Cl. CPC G06Q 10/20; G01R 31/56; G01R 21/133; G06Q 50/06; H02J 13/00002; G06Q 50/12; G05B 23/0259; G07F 13/02; G06Q 10/087

(57) ABSTRACT

Systems and methods are provided for determining appliance service requirements including: receiving an electrical signal indicative of an electrical load of an appliance over a period of time; determining an activity performed by the appliance by comparing the received electrical signal to an electrical signature of the appliance performing the activity; and responsively to determining the activity, determining a required service for the appliance.

### FIELD OF THE INVENTION

The present invention relates to a system and method for monitoring electrical use, in particular to remote monitoring of electrical appliances.

### BACKGROUND

Electric appliances used for dispensing products, such as coffee machines, water coolers, soft drink and alcoholic beverage vending machines, ice cream and yogurt dispensing machines, and the like, often require ongoing service by appliance vendors, regardless of whether they are in residential or commercial use. Typical service includes repair maintenance, routine, preventive maintenance, and restocking of consumable products associated with the operation of the machine, be it beverages or other products dispensed or auxiliary products, such as plastic/paper cups, ice-cream cones, or any other container product for consuming the appliance output.

When a commercial appliance breaks down, its operator (such as a restaurant operator) may lose customers and revenues, hence there is a need to minimize the downtime of appliances due to malfunctions. Dispensing appliances also require routine service, such as changing filters or other parts after a predetermined time (e.g., every 3 months) or predetermined number of operations (e.g., after serving 1,000 cups of ice cream).

In addition to such servicing, dispensing appliances require regular delivery of consumable products. Delivery of consumables to business establishments is typically not optimized to coincide with the internal “inventory” level of the dispensing machine, because the consumable provider is not aware of the real consumable consumption. Either the business operator must place an order to receive consumable products, or service is provided according to a predetermined schedule. Sometimes, this means that an appliance runs out of its internal inventory and cannot be operated until stock is replenished by the appliance vendor.

There is thus, within the field of customer relationship management (CRM), a need for appliance vendors (also referred to herein as “providers”) to be better informed about the status of dispensing appliances and the actual consumption of consumable products in order to provide appliance operators with faster and more efficient on-time delivery of both maintenance services and consumables.

### SUMMARY

Embodiments of the present invention provide methods and systems for remotely determining service requirements of electrical dispensing appliances including a need to replenish consumable products on a timely and efficient basis. A Connected Consumer System (CCS) is a connected appliance monitoring platform for companies that operate a product subscription service for dispensing appliances for products such as coffee, mineral water, soft ice cream and yogurt, beer and soft drinks, where products are supplied by the company to the operator as raw materials, together with an electrical appliance that prepares the food or drink. The CCS enables device monitoring, analyzing consumption habits and optimizing the replenishment of raw materials. The CCS also identifies wear or poor maintenance and identifies a need for predictive (i.e., preventive) maintenance, indicating that a routine service was not performed on time.

There is therefore provided, by embodiments of the present invention, a computing system, comprising at least one processor and at least one memory communicatively coupled to the at least one processor and comprising computer-readable instructions that when executed by the at least one processor cause the computing system to identify an activity of an electrical appliance, by implementing steps of: measuring parameters of electrical activity of the electrical appliance over a period of time; analyzing the parameters of electrical activity to identify one or more activities of the appliance; and responsively to the identification of the one or more activities, determining a required service for the appliance.

The one or more activities may include dispensing of consumable products and the service required may be restocking of the consumable products. Restocking may include preparing a consumable product replenishment schedule based on a determined quantity of consumable products dispensed. The consumable products may include one or more of: water, coffee, a soft drink, an alcoholic drink, cups, ice-cream cones, soap, and detergents. Restocking may further include comparing the quantity of consumable products calculated to be consumed to the quantity of consumable products ordered by an operator of the electrical appliance. The one or more activities of the appliance may include one or more of: preparing a, foaming milk, preparing a cup of water, cup of coffee of a particular type, serving a soft drink, serving an alcoholic beverage, serving ice cream, serving yogurt, heating an element, cooling an element, and performing a wash cycle.

When identifying an activity, the system can identify specific types of the same activity. For example, the particular types of cup of coffee can include: short espresso (with, without sugar), long espresso (with, without sugar), latte (with, without sugar), cappuccino (with, without sugar) etc.

In some embodiments, a smart plug connects the electrical appliance to an electricity source, measures the electric activity of the appliances, and communicates the measurement to the computing system.

In some embodiments, the electrical activity of the appliance is measured at least one time per second.

Determining the required service may include identifying a fault in the appliance operation providing an alert to maintenance staff. Alternatively or additionally, determining the required service may include determining that a maintenance activity for the appliance was not performed on time.

Dynamic Time Warping (DTW) may be used as a method for identifying the one or more activities.

The steps performed by the system may further include providing, for each identified activity, corresponding activity parameters comprising length of activity, electric consumption and anomalies detected. An initial step of training the computing system to recognize one or more activities of the appliance may include triggering the one or more activities and measuring the electric activity associated with each activity. Determining a service required by the appliance may also include identifying degradation or a malfunction of the electrical appliance and responsively issuing maintenance recommendations, according to predefined configuration rules. One type of maintenance recommendations can be predictive maintenance (for example, when a degradation that is not a malfunction is noticed) so the recommended maintenance will improve the device functionality (reduce electric consumption, increase operation speed, avoid degradation or malfunction etc.). Another type of maintenance recommendations can be of required maintenance either as scheduled maintenance (for example, after every 1,000 cups of coffee served) or when a current or imminent fault is identified (for example, heating cycle is longer than normal).

### BRIEF DESCRIPTION OF DRAWINGS

For a better understanding of various embodiments of the invention and to show how the same may be carried into effect, reference is made, by way of example, to the accompanying drawings. Structural details of the invention are shown to provide a fundamental understanding of the invention, the description, taken with the drawings, making apparent to those skilled in the art how the several forms of the invention may be embodied in practice. In the accompanying drawings:

FIG. 1 is a schematic diagram of a system for automated appliance monitoring, according to some embodiments of the present invention;

FIG. 2 is a flow diagram of a process for automated appliance monitoring, according to some embodiments of the present invention;

FIGS. 3A and 3B are schematic illustrations of an electrical monitoring wall plug for automated appliance monitoring, according to some embodiments of the present invention; and

FIGS. 4-10 are graphs of electrical signals received from electrical appliances and indicative of appliance operation, according to some embodiments of the present invention.

### DETAILED DESCRIPTION

It is to be understood that the invention and its application are not limited to the methods and systems described below or to the arrangement of the components set forth or illustrated in the drawings, but are applicable to other embodiments that may be practiced or carried out in various ways.

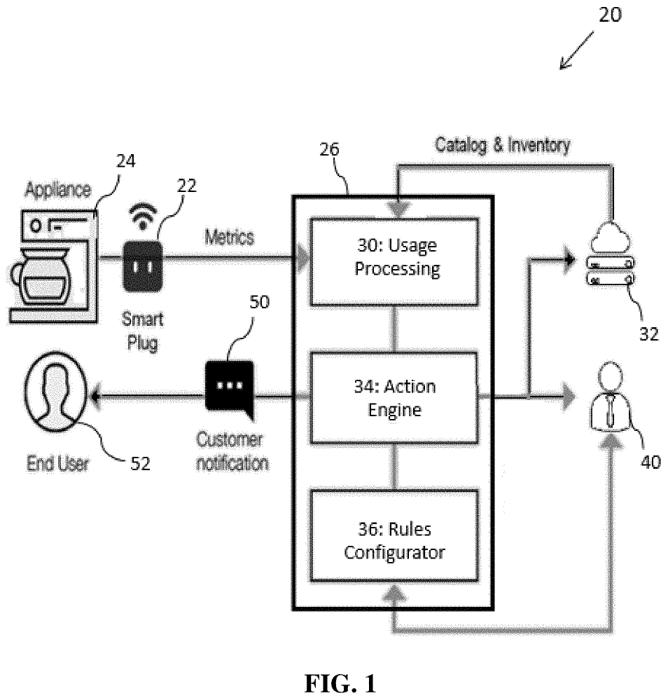

FIG. 1 is a schematic diagram of a Connected Consumer System (CCS) 20 for automated appliance monitoring, according to some embodiments of the present invention. The CCS 20 includes two main components. The first component is a “smart plug” 22, such as an electrical socket wall plug, that connects an electrical appliance 24 to a source of electrical power while also measuring and transmitting electrical operating parameters of the appliances, such as current usage or power consumption data, to a remote “CCS” server 26. The electrical appliance 24 may be any device, for example, one that is managed by a food appliance vendor, such as a commercial coffee machine, ice cream dispenser, water cooler, soft drink dispenser, etc. These devices typically dispense consumable products (e.g., coffee, soft drinks, and ice cream) that must be replenished. The electrical appliance may also be other types of electrical equipment such as refrigerators and heaters.

The second main component of the CCS 20 is the CCS server 26, which analyzes the data received from the smart plug 22 to determine product consumption of the electrical appliance 24 and to provide replenishment recommendations, as well as to provide cleaning or service alerts and pre-failure forecasts. Typically, the smart plug 22 is configured to transmit measured electrical readings to the “CCS” server 26 every second, but may the frequency may be modified depending on the type of appliance. Communications may be performed by a cellular transmission protocol, such as GSM, or by other communications means, such as Wi-Fi transmission to a wireless on-site router, providing internet transmission to the CCS server. Alternatively, the communication to the server may be wired, for example, via electric wires. In some embodiments, the CCS server may be operated as a cloud-based server.

The primary analysis performed by the CCS server 26 is performed by a usage processing module 30, which is configured to identify and to “translate” the electrical signals (the “electrical signatures”) measured from the electrical appliance 24 into information about the activities performed by the electrical appliance and about the appliance's operational status. From the electrical signals, which are typically tracked over time, the usage processing module determines if an appliance is in need of servicing. Servicing may be a routine service call to restock a product dispensed by the appliance. Alternatively or additionally, a required service may be maintenance work that is required because the appliance is not working properly or recommended preventive maintenance to improve the appliance (consume less electricity, faster dispensing, increase longevity of parts etc.).

Electrical appliances for dispensing products, in particular food and drink products, typically have multiple electrical elements, which may include elements such as motors, compressors, pumps, lights, and heating and/or cooling elements. These elements typically operate intermittently, and the power consumption of each element is typically different. The power consumption of an appliance is the sum of the power consumption of each element, meaning that as each element turns on and off, a waveform of the appliance's power consumption indicates the sum of the power consumption of each element.

Different activities of an appliance, such as self-cleaning or dispensing soda, involve the operation of different elements of the appliance. When a given activity (or “operation”) is performed, the waveform of the appliance's power consumption (or current, or other electrical parameter) shows a “signature” that may be correlated to the activity. The usage processing module 30 is trained by a machine learning algorithm (such as “supervised learning”) to identify the correspondence of electrical signatures to distinct activities of a given model of appliance. In some embodiments, training that is based on a given model may be extended to apply to a specific appliance in the field.

Training is applied to classify signal signatures according to given activities of appliances as well as to determine deviations from normal operation (i.e., anomaly detection, indicating required maintenance). Training is done by performing a given activity several times on the same appliance and/or by performing the given activity one or more times on similar appliances (for example, 10 identical coffee machines, as each machine operates slightly different).

Classification of signals may include, for example, correlation of a certain signal signature (pattern) of a coffee machine to a specific action, for example, not merely to making coffee, but more precisely to a type of coffee process, e.g., espresso, or latte, long or short, with or without sugar. The usage processing module may also correlate signal signatures to maintenance-related activities, such as self-cleaning, container changes, and heating and cooling cycles. The module may also be trained to identify anomalies in signals, which may indicate appliance wear that requires maintenance. Correlation to classified signals may be performed by methods known in the art, such as dynamic time warping, by which a “representative” signal signature for a given appliance activity is compared to a received signal by performing “warping” functions to test similarity.

The usage processing module 30 typically references a vendor database system 32, which may include product catalogues stored in an enterprise resource planning system (ERP), as well as customer-specific data stored in a customer relationship management (CRM) system. The vendor database system 32 may provide input to the usage module 30 regarding appliance consumable requirements and other vendor catalog information. The vendor database system 32 may also include supply plans. The amount of consumables determined by the usage processing module to have been used by an appliance, together with the data from the vendor database 32, may then be processed by an action engine 34 to determine whether vendor action is required.

For example, the usage processing module may determine that based on the received signals over a period of a week, that is, based on a running total of all actions identified, a given coffee machine at a site of an operator has produced 620 cups of coffee of various types, which in total, according to specifications in the vendor database, have utilized 14 pounds of coffee beans. The database specifications may also indicate the coffee machine capacity and a “supply plan” for the product, the supply plan being a type of configuration rule that a vendor may enter by an interface referred to as a rules configurator 36. If for example, the machine has a capacity of 15 pounds, and the supply plan indicates that a replenishment order should be initiated when there is one pound or less of beans, then the action engine 34 enters an order for replenishment of the operator's coffee machine. Order details (e.g., product, operator) may be sent to the vendor database system 32 (e.g., an ERP function of the database system) for initiating delivery and billing.

In addition to triggering a renewal order, the action engine may perform trend analysis, updating trend data regarding an appliance's typical consumption pattern. In addition, a salesperson 40 (or CRM system) may be notified by the action engine, especially if the consumption is determined to be unusual with respect to the operator's typical usage, that is, either faster or slower than a typically range. The action engine may also determine potentially suspicious activity such as using non-service provider's supplies (e.g., over-consumption of consumables that do not appear in receipts).

Output from the action engine may also be provided to a customer notification system 50, which may provide information to a customer 52 (i.e., the appliance operator), about scheduled replenishment and/or maintenance visits.

The analyses performed by the CCS server enable optimization of replenishment schedules and predictive maintenance, as well as enabling customer analytics that can drive new sales. For example, analysis may indicate that an operator's usage is trending up, meaning that acquisition of a larger machine may be warranted. The CCS may determine that electrical signals indicate wear or poor maintenance and may identify a need for predictive (i.e., preventive) maintenance, based on electrical signatures generated by an appliance that indicate that a routine service was not performed on time.

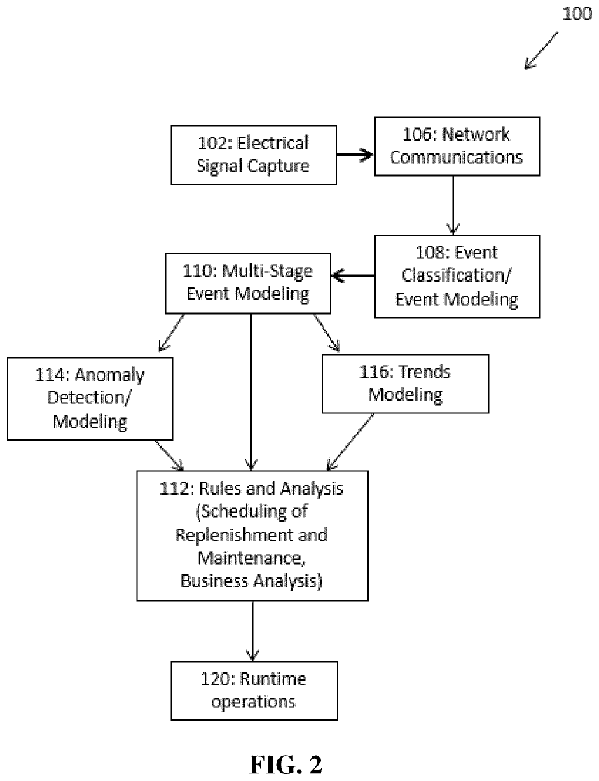

FIG. 2 is a flow diagram of a process 100 for training a system of appliance monitoring, according to some embodiments of the present invention. As described above, the system is trained to recognize signal signatures, also referred to herein as “events.” Training may initially be performed on appliances configured to operate in a test laboratory. Subsequently, training may continue while the system is operational. That is, while the system is operating to monitor an appliance, the training model may continue to be fine-tuned to better correspond with actual field results. In addition, as described above, training may be done to be specific for individual appliances in the field (i.e., at specific residences and commercial sites), rather than merely for appliance models.

The training process includes acquiring electrical signals indicative of an electrical load of an appliance at a step 102. The electrical signals are typically captured by a smart plug 22 as described above. The signals captured may be measurements of an electrical parameter such as power consumption or current.

At a step 106, the signals are packaged as messages and transmitted to a server. Transmission is then performed at a step 106, which may be performed wirelessly by known communications protocols, such as cellular phone or internet protocols. Smart meter transmission protocols may also be used.

At a step 108, the signals are processed by a machine learning framework, or classification engine, which is trained to recognize, or otherwise “classify,” signatures corresponding with given activities being performed by an appliance under test (i.e., an appliance for which training is being performed). Learning of signal “signatures” may include classification and grouping of signals by various methods known in the art. In some embodiments, signal signatures are recognized as being similar by a method of signal process referred to as Dynamic Time Warping (DTW), which may be the basis of classification by methods such as the k-nearest neighbors (kNN) algorithm. The classification may be accelerated with a properly selected lower bound (LB), such as may be obtained by the LB Keogh method. Additional classification frameworks may be implemented based on known algorithms such as XGBoost, deep convolutional neural networks (CNNs), and recurrent neural networks (RNNs).

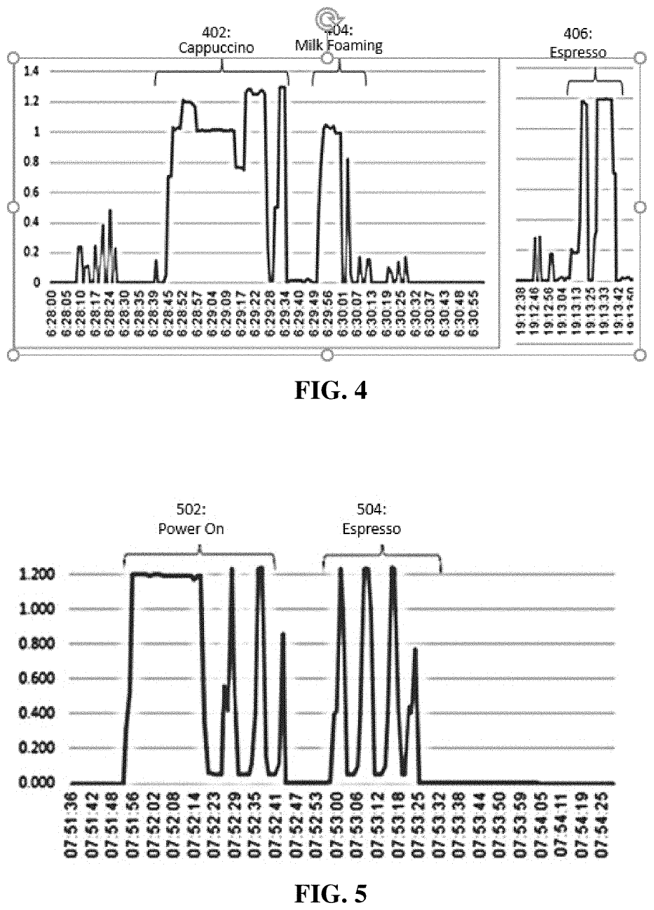

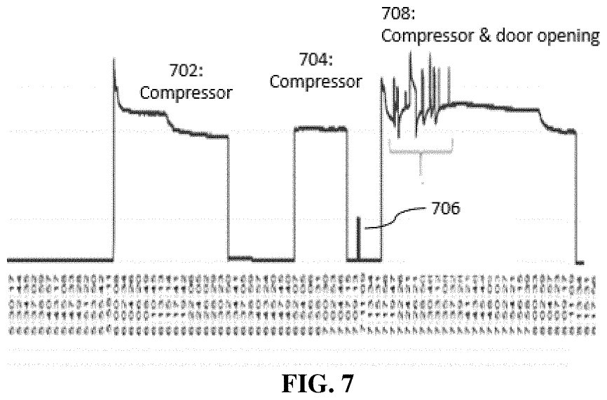

A learned activity may be, for example, preparation of a drink by a soda fountain machine, or by an espresso machine, or it may be specific operation of an element of a machine, such as a compressor of a freezer. Training of the machine learning framework typically includes providing “labels” to the framework that indicate specific machine activities, the activities being performed concurrently with the acquisition of the signals. Examples of signal signatures identified with specific events are described below with respect to FIGS. 4-7.

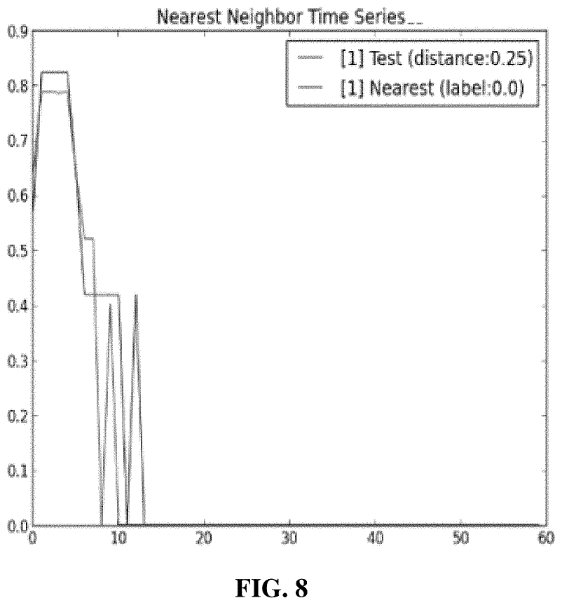

In some embodiments, a “representative” signature may be created. Classifications or other machine learning frameworks may be subsequently applied during the runtime operating mode of the system (step 120, described below), to associate or “correlate” acquired signatures with known events. DTW may also be used for association of new signals with events, as indicated in FIGS. 8-10.

At a step 110, complex activities that involve multiple individual activities are also “learned.” For example, some appliances perform self-cleaning tasks that involve multiple steps, each step being indicated as an independent signal signature.

At a step 112, results of the event and multi-stage event modeling are associated with rules performed by the action engine 34, such as scheduling of replenishment visits to a customer site. Scheduling of maintenance can also be performed, based on detection of anomalies in the signals, which may be modeled at a step 114. In addition, rules for trends, such as increasing consumption can be configured at a step 116, and then applied by the action engine in the process of business analysis as described above. At a step 120, the classification or other machine learning frameworks developed may be used by the usage processing module 30 during runtime to monitor machines (or appliances) and to identify machine actions according to signal signatures.

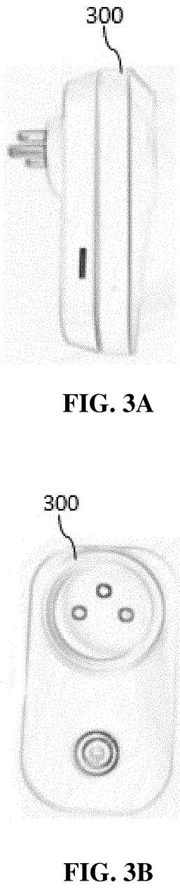

FIGS. 3A and 3B are schematic illustrations of a respective side and front views of the smart plug 22 for automated appliance monitoring, according to some embodiments of the present invention. The smart plug may simply fit into an electrical socket and provide a complementary socket for an appliance, such that measurement of electrical parameters requires no additional wiring and is essentially transparent to customers. Typically, each smart plug has a unique address which is also transmitted to the CCS server, so that appliances may be correlated to their measured signals.

FIGS. 4-10 are graphs of electrical signals from electrical appliances, indicative of appliance operation, according to some embodiments of the present invention. The x-axis for the graphs are in seconds, but could be in different time units depending on the type of appliance being measured. The y-axis for the graphs are in normalized units representing power (such as watts). Graphs may also be in units of current (e.g., amperes).

FIG. 4 indicates three exemplary signal signatures, as measured from a commercial coffee machine. Signature 402 was measured while the machine was preparing cappuccino, signature 404 while the machine was preparing milk foam, and signature 406 while the machine was preparing espresso.

FIG. 5 similarly indicates two exemplary signal signatures, as measured from a commercial coffee machine, where signature 502 indicates usage while the machine was powering on, and signature 504 while preparing espresso. It may be noted that signatures 406 and 504, which may be from the same machine, both when preparing espresso, can be quite different, as different elements of the machine may be operating at the same time that espresso is being prepared. For example, the machine may be heating water during one event of espresso preparation, but not in the second. The machine learning classification system is trained to recognize all such variations.

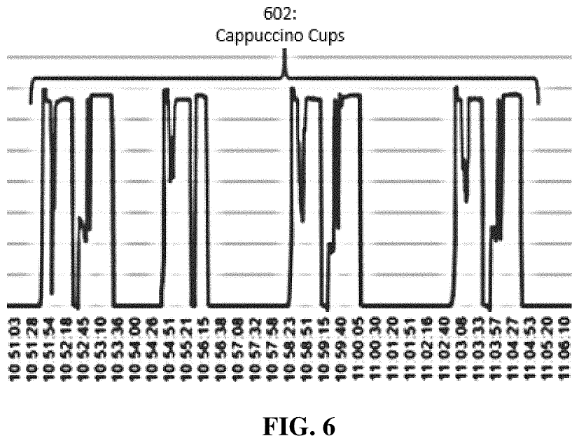

The variations of signatures are also indicated in FIG. 6, which shows a signal from a cooler, such as drink dispenser, which dispensing drinks when a door is opened. As indicated, signatures 702 and 704 indicate compressor operation. Signature 706 indicates a brief door opening (such as may be caused by a light being turned on). Signature 708 is a complex signature of multiple door openings while the compressor is operating (the compressor operates because the open door warms the cooler compartment). The usage processing module may be configured to count each door opening, when this indicates individual item dispensing.

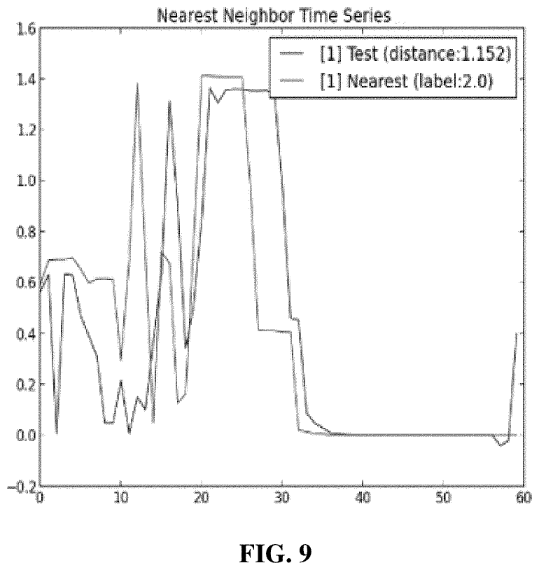

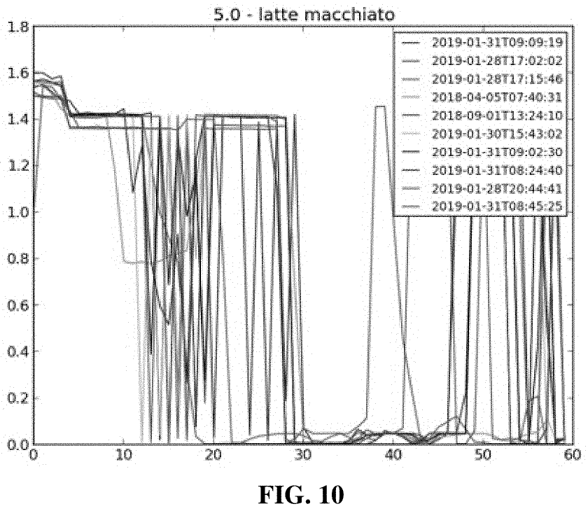

FIGS. 8-10 indicate processes of correlating measured signatures (“test” signatures) and signatures representing a type of event (“nearest” signatures), according to some embodiments of the present invention. FIGS. 8 and 9 shows comparisons between pairs of similar signatures, one being previously measured (“nearest”, meaning the nearest of all collected signals during training) and newly acquired during runtime operation (indicated as “test”). As described above, the correlation may be performed by a method of signal process referred to as Dynamic Time Warping (DTW). Other methods of signal processing correspondence known in the art may also be applied. FIG. 10 shows a collection of ten signatures acquired during training of an espresso machine, during preparation of a latte macchiato drink. All of the signatures are different in some respect. Training parameters of “distance” may be adjusted to account for the differences and group all signatures in a common classification. Alternatively, outlier signatures may be removed to prevent subsequent false positives. For example, the signature in purple, having a peak at 40 seconds may be removed.

All or part of the process 100, as implemented by the system 20, may be implemented in digital electronic circuitry, or in computer hardware, firmware, software, or in combinations thereof. All or part of the system and process can be implemented as a computer program product, tangibly embodied in an information carrier, such as a machine-readable storage device or in a propagated signal, for execution by, or to control the operation of, data processing apparatus, such as a programmable processor, computer, or deployed to be executed on multiple computers at one website or distributed across multiple websites. Memory storage may also include multiple distributed memory units, including one or more types of storage media. Examples of storage media include, but are not limited to, magnetic media, optical media, and integrated circuits such as read-only memory devices (ROM) and random access memory (RAM). A computing system configured to implement the system may have one or more processors and one or more network interface modules. Processors may be configured as a multi-processing or distributed processing system. Network interface modules may control the sending and receiving of data packets over networks. Data, including sequences of instructions, may be delivered from computer RAM to a processor, may be carried over a wireless transmission medium, and/or may be formatted according to numerous formats, standards or protocols, such as Bluetooth, TDMA, CDMA, and 3G.

It is to be understood that the scope of the present invention includes variations and modifications thereof which would occur to persons skilled in the art upon reading the foregoing description and which are not disclosed in the prior art.

1. A computing system, comprising at least one processor and at least one memory communicatively coupled to the at least one processor and comprising computer-readable instructions that when executed by the at least one processor cause the computing system to implement the steps of:
(i) receiving an electrical signal indicative of an electrical load of an appliance over a period of time;
(ii) determining an activity performed by the appliance by comparing the received electrical signal to a previously learned electrical signature of the appliance performing the activity; and
(iii) responsively to determining the activity, determining a required service for the appliance.

2. The computing system of claim 1, wherein the activity includes dispensing of consumable products and wherein the required service includes restocking of the consumable products.

3. The computing system of claim 2, further comprising the step of preparing a consumable product replenishment schedule by determining a quantity of the consumable products dispensed.

4. The computing system of claim 2, wherein the consumable products comprise one or more of:
water, coffee, a soft drink, an alcoholic drink, cups, ice-cream cones, soap, and detergents.

5. The computing system of claim 2, further comprising the step of comparing a quantity of the consumable products determined to be consumed to a quantity of the consumable products ordered by an operator of the appliance.

6. The computing system of claim 1, wherein the activity comprises one or more of:
preparing a cup of coffee of a particular type, foaming milk, preparing a cup of water, serving a soft drink, serving an alcoholic beverage, serving ice cream, serving yogurt, heating an element, cooling an element, and performing a wash cycle.

7. The computing system of claim 1, further comprising a smart plug, wherein a smart plug connects the electrical appliance to an electricity source, and wherein the smart plug measures the electric activity of the appliances and communicates it to the computing system.

8. The computing system of claim 1, wherein the electrical signal is measured at least one time per second.

9. The computing system of claim 1, wherein determining the required service comprises identifying a fault in the appliance operation and further comprises providing an alert to maintenance staff.

10. The computing system of claim 1, wherein determining the required service comprises determining that a maintenance activity for the appliance was not performed on time.

11. The computing system of claim 1, wherein the received electrical signal is compared to the electrical signature of the appliance by Dynamic Time Warping (DTW) to determine the performed activity.

12. The computing system of claim 1, further comprising determining, in addition to the activity, corresponding activity parameters comprising length of activity, electric consumption and anomalies detected.

13. The computing system of claim 1, further comprising an initial step of training the computing system to creating the electrical signature of the appliance by triggering the activity and measuring the electric signals associated with the activity.

14. The computing system of claim 1, wherein determining a service required by the appliance comprises identifying degradation or a malfunction of the appliance and issuing maintenance recommendations.

15. A method for determining appliance service requirements, performed by a computing system having at least one processor and at least one memory communicatively coupled to the at least one processor and having computer-readable instructions that when executed by the at least one processor cause the computing system to implement the method, comprising:
(i) receiving an electrical signal indicative of an electrical load of an appliance over a period of time;
(ii) determining an activity performed by the appliance by comparing the received electrical signal to a previously learned electrical signature of the appliance performing the activity; and
(iii) responsively to determining the activity, determining a required service for the appliance.
